(19) United States
(12) Patent Application Publication
(10) Pub. No.: US 2017/0162557 A1
(43) Pub. Date: Jun. 8, 2017

(54) TRENCH BASED CHARGE PUMP DEVICE

(71) Applicant: GLOBALFOUNDRIES Inc., Grand Cayman (KY)

(72) Inventors: Hans-Peter Moll, Dresden (DE); Peter Baars, Dresden (DE); Juergen Faul, Radebeul (DE)

(21) Appl. No.: 14/958,150

(22) Filed: Dec. 3, 2015

(51) Int. Cl. H01L 27/02; H01L 29/66; H01L 21/84; H01L 29/417; H01L 27/12; H01L 27/07; H01L 49/02

(52) U.S. Cl. CPC H01L 27/0222; H01L 27/0733; H01L 29/66477; H01L 28/40; H01L 29/41783; H01L 27/1207; H01L 21/84

(57) ABSTRACT

A semiconductor device is provided including a fully depleted silicon-on-insulator (FDSOI) substrate and a charge pump device, wherein the FDSOI substrate comprises a semiconductor bulk substrate, and the charge pump device comprises a transistor device formed in and on the FDSOI substrate, and a trench capacitor formed in the semiconductor bulk substrate and electrically connected to the transistor device. A semiconductor device is further provided including a semiconductor bulk substrate, a first transistor device comprising a first source/drain region, a second transistor device comprising a second source/drain region, a first trench capacitor comprising a first inner capacitor electrode and a first outer capacitor electrode, and a second trench capacitor comprising a second inner capacitor electrode and a second outer capacitor electrode, wherein the first inner capacitor electrode is connected to the first source/drain region and the second inner capacitor electrode is connected to the second source/drain region.

### BACKGROUND

1. Field of the Disclosure

Generally, the present disclosure relates to the field of integrated circuits and semiconductor devices and, more particularly, to the formation of a charge pump device, more particularly, the formation of a charge pump device for back-biasing an FDSOI transistor device.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of electronic circuits, field effect transistors represent one important type of circuit element that substantially determines performance of the integrated circuits. Generally, a plurality of process technologies are currently practiced for forming field effect transistors (FETs), wherein, for many types of complex circuitry, metal-oxide-semiconductor (MOS) technology is currently one of the most promising approaches due to the superior characteristics in view of operating speed and/or power consumption and/or cost efficiency. During the fabrication of complex integrated circuits using, for instance, CMOS technology, millions of N-channel transistors and P-channel transistors are formed on a substrate including a crystalline semiconductor layer.

Nowadays, as an alternative to bulk devices, FETs are also built on silicon-on-insulator (SOI), in particular Fully Depleted silicon-on-insulator (FDSOI), substrates. The channels of the FETs are formed in thin semiconductor layers, typically including or made of silicon material, wherein the semiconductor layers are formed on insulating layers, buried oxide (BOX) layers that are formed on semiconductor bulk substrates. One severe problem caused by the aggressive downscaling of the semiconductor devices must be seen in the occurrence of leakage currents. Since leakage currents depend on the threshold voltages of the FETs, substrate biasing (back biasing) can reduce leakage power. With this advanced technique, the substrate or the appropriate well is biased to raise the transistor thresholds, thereby reducing leakage currents. In P-channel MOS (PMOS) devices, the body of the transistor is biased to a voltage higher than the positive supply voltage V_{DD}. In N-channel MOS (NMOS) devices, the body of the transistor is biased to a voltage lower than the negative supply voltage V_{SS}. Similar to the grid of standard cells, a grid of tap cells is commonly used in the integrated circuit design to provide for the body bias of the transistors. The tap cells have to create electrical connections between a network providing biasing voltages P⁺/N⁺ regions residing under the BOX layers of SOI, particularly FDSOI, substrates. Each standard cell row must have at least one (body- or well-) tap cell. However, usually designers have a rule of one tap cell placed in a standard cell row per every certain distance at regular intervals.

In order to bias the back gates of the NMOS and PMOS transistor devices, voltages need to be created by charge pumps which are custom blocks that output V_{SS} and V_{OUT}. FIG. 1 illustrates a prototypic circuit element providing DC-DC-conversion without the need for any inductors or diodes. The charge pump depicted here is dedicated to generate voltages as low as −V_{DD}, where V_{DD} is the external supply voltage, and is thus required for enabling a back gate range from −V_{DD} to V_{DD}. Other charge pumps to extend that range beyond these settings can easily be derived from the present embodiment.

The circuit element shown in FIG. 1 comprises four switches S1, S2, S3 and S4, capacitors C1 and C2, and a diode D, as well as a voltage input source V+ and a voltage output V_{OUT}. An oscillator (not shown in FIG. 1) supplies a control signal, thereby driving periodic switching of the four switches S1, S2, S3 and S4. In operation, closing S1 and S3 charges the capacitor C1 to V+ in a first half of a cycle. In the second half of the cycle, S1 and S3 open and S2 and S4 close. Thereby, the positive terminal of C1 is connected to ground and the negative terminal is connected to V_{OUT}. C1 is then in parallel with the capacitor C2. If the voltage across C2 is smaller than that across C1, charge flows from C1 to C2 until the voltage across C2 reaches the negative value of V+ (with no load present). With appropriate changes made in the external connections, the output voltage may be, for example, a multiple or fraction of the input voltage.

In the art, charge pumps, for example, realized based on the configuration illustrated in FIG. 1, comprise planar capacitors and additional transistor devices. The isolated planar capacitors formed in the SOI area of a semiconductor device do need much space (large spacing rules). The demand for a large space becomes more and more disadvantageous in the course of aggressive overall downscaling of semiconductor technology.

In view of the situation described above, the present disclosure provides a technique of providing charge pump devices comprising capacitors with a lower demand for a spatial area covered in an SOI device as compared to the art.

### SUMMARY OF THE DISCLOSURE

The following presents a simplified summary of the disclosure in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally the subject matter disclosed herein relates to the formation of semiconductor devices comprising transistor devices, and, more particularly, integrated circuits with (MOS)FETs including means for back biasing of the transistor devices.

A semiconductor device is provided including a Fully Depleted Silicon-on-Insulator (FDSOI) substrate and a charge pump device, wherein the FDSOI substrate comprises a semiconductor bulk substrate. The charge pump device comprises a transistor device formed in and on the FDSOI substrate and a trench capacitor formed in the semiconductor bulk substrate and electrically connected to the transistor device. By forming the charge pump device by the connected transistor device and trench capacitor, a compact design for the charge pump device may be achieved that needs less space than the charge pumps known in the art.

Further, a semiconductor device (particularly a charge pump device) is provided with a semiconductor bulk substrate, a first transistor device comprising a first source/drain region, a second transistor device comprising a second source/drain region, a first trench capacitor comprising a first inner capacitor electrode and a first outer capacitor electrode, and a second trench capacitor comprising a second inner capacitor electrode and a second outer capacitor electrode. The first inner capacitor electrode is connected to the first source/drain region and the second inner capacitor electrode is connected to the second source/drain region. The first outer capacitor electrode and the second outer capacitor electrode may be connected to the semiconductor bulk substrate.

Furthermore, a semiconductor device (particularly a charge pump device) is provided with a first trench capacitor comprising a first inner capacitor electrode and a first outer capacitor electrode, a second trench capacitor comprising a second inner capacitor electrode and a second outer capacitor electrode, a first switching device, and a second switching device. The first inner capacitor electrode and the second outer capacitor electrode are connectable to each other by the first switching device and the first outer capacitor electrode and the second inner capacitor electrode are connectable to each other by the second switching device. The first and the second trench capacitor are electrically cross-coupled to each other via the first and second switching devices. Electrical connection between the first inner capacitor electrode and the second outer capacitor electrode is established by closing the first switching device and electrical connection between the first outer capacitor electrode and the second inner capacitor electrode is established by closing the second switching device. The first switching device may comprise or consist of a transistor device and the second trench capacitor may comprise or consist of another transistor device wherein, particularly, the transistor devices may share a common gate electrode (poly line).

Furthermore, a method of manufacturing a semiconductor device, in particular, a charge pump device, is provided including the steps of providing a semiconductor substrate comprising a semiconductor bulk substrate, a buried oxide layer formed on the semiconductor bulk substrate and a semiconductor layer formed on the buried oxide layer, forming a first transistor device and a second transistor device in and over the semiconductor substrate, and forming a first and a second trench capacitor at least partially in the semiconductor substrate. Forming the first transistor device includes forming a first raised source/drain region on the semiconductor layer and forming the second transistor device comprises forming a second source/drain region on the semiconductor layer, and forming the first trench capacitor includes forming a first inner capacitor electrode in contact with the first source/drain region and a first outer capacitor electrode at least partially in the semiconductor substrate and forming the second trench capacitor includes forming a second inner capacitor electrode in contact with the second source/drain region and a second outer capacitor electrode at least partially in the semiconductor substrate.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a basic circuit element that may be used in a charge pump according to the art;

FIG. 2 illustrates a charge pump configuration according to an example of the present disclosure;

FIGS. 3a-3d show an example for a semiconductor device realizing a configuration similar to that shown in FIG. 2;

FIGS. 4a-4f illustrate a process flow for manufacturing a semiconductor device according to an example of the present disclosure; and

FIGS. 5a-5e show examples for electrical contacts formed between the wafer bulk and raised source/drain regions of an exemplary semiconductor device.

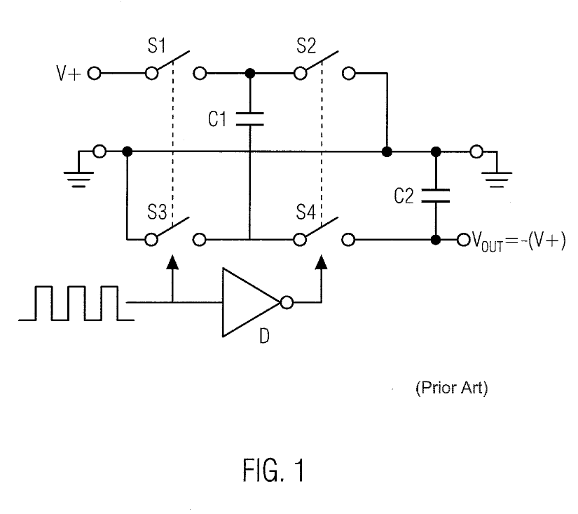

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The following embodiments are described in sufficient detail to enable those skilled in the art to make use of the disclosure. It is to be understood that other embodiments would be evident, based on the present disclosure, and that system, structure, process or mechanical changes may be made without departing from the scope of the present disclosure. In the following description, numeral-specific details are given to provide a thorough understanding of the disclosure. However, it would be apparent that the embodiments of the disclosure may be practiced without the specific details. In order to avoid obscuring the present disclosure, some well-known circuits, system configurations, structure configurations and process steps are not disclosed in detail.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As will be readily apparent to those skilled in the art upon a complete reading of the present application, the present methods are applicable to a variety of technologies, for example, NMOS, PMOS, CMOS, etc., and is readily applicable to a variety of devices, including, but not limited to, logic devices, SRAM devices, etc., particularly in the context of FDSOI technologies used for manufacturing integrated circuits (ICs). Generally, manufacturing techniques and semiconductor devices in which back (substrate)-biased N-channel transistors and/or P-channel transistors may be formed are described herein. The manufacturing techniques may be integrated in CMOS manufacturing processes. The techniques and technologies described herein may be utilized to fabricate MOS integrated circuit devices, including NMOS integrated circuit devices, PMOS integrated circuit devices, and CMOS integrated circuit devices. In particular, the process steps described herein are utilized in conjunction with any semiconductor device fabrication process that forms gate structures for integrated circuits, including both planar and non-planar integrated circuits. Although the term “MOS” properly refers to a device having a metal gate electrode and an oxide gate insulator, that term is used throughout to refer to any semiconductor device that includes a conductive gate electrode (whether metal or other conductive material) that is positioned over a gate insulator (whether oxide or other insulator) which, in turn, is positioned over a semiconductor bulk substrate.

The present disclosure, generally, provides charge pump devices comprising trench capacitors that are particularly suitable for dynamic back-biasing of transistor devices, for example, dynamic back-biasing of FDSOI (MOS)FETs.

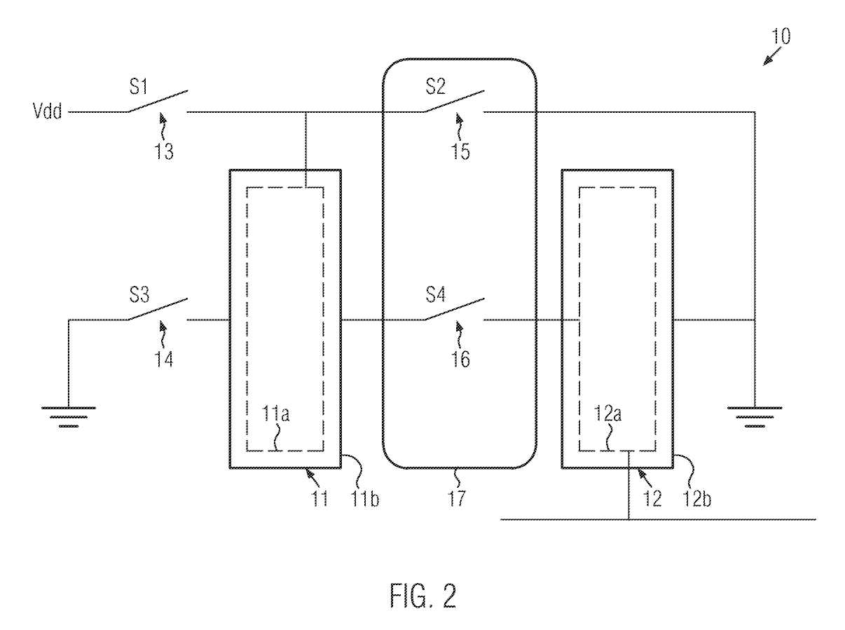

FIG. 2 illustrates a charge pump configuration 10 according to an example of the present disclosure. The charge pump configuration 10 comprises a first trench capacitor 11 with an inner electrode 11a and an outer electrode 11b and a second trench capacitor 12 with an inner electrode 12a and an outer electrode 12b. Further, the charge pump configuration 10 comprises a first switch 13, a second switch 14, a third switch 15 and a fourth switch 16. All of the four switches 13, 14, 15 and 16 may be realized by transistor devices. The third and fourth (transistor) switches 15 and 16 may be coupled via a common gate electrode 17. The first switch 13 provides for electrical connection with V_{DD} and the second switch 14 provides for electrical connection to ground. The third switch 15 provides for electrical connection of the inner electrode 11a of the first trench capacitor 11 and the outer electrode 12b of the second trench capacitor 12, and the fourth switch 16 provides for electrical connection of the outer electrode 11b of the first trench capacitor 11 and the inner electrode 12a of the second trench capacitor 12. In other words, the inner and outer electrodes, 11a, 11b, 12a and 12b, of the first and second trench capacitors 11 and 12 are cross-coupled to each other via the third and fourth switches 15 and 16. In operation, the switches 13, 14, 15 and 16 may be controlled to obtain an output voltage V_{OUT} of −V_{DD}, for example.

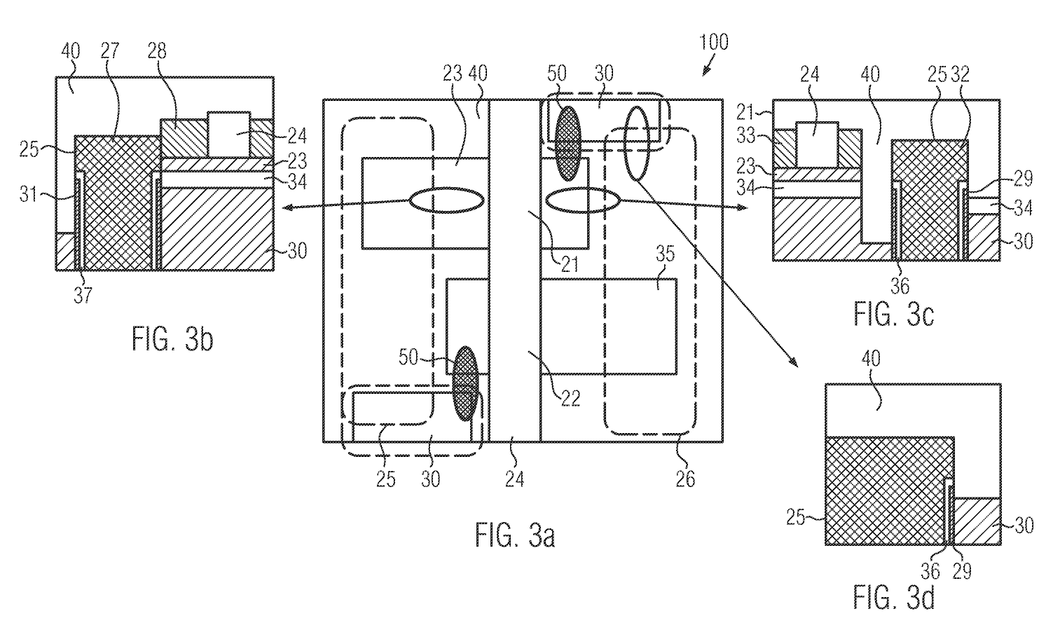

An example for a semiconductor device 100 realizing the configuration shown in FIG. 2 is illustrated in FIGS. 3a-3d. FIG. 3a shows a top view and FIGS. 3b, 3c and 3d show sectional views of the semiconductor device 100. The semiconductor device 100 comprises a first transistor switch (switching transistor) 21 and a second transistor switch (switching transistor) 22 formed on and in a first semiconductor layer 23 and a second semiconductor layer 35, respectively. The first semiconductor layer 23 and the second semiconductor layer 35 provide the channel regions of the transistor switches 21 and 22. It is noted that the semiconductor layer 23 and/or the semiconductor layer 35 may comprise an embedded SiGe material in the channel region of the transistor switches 21 and 22, respectively. The transistor switches 21 and 22 share a common gate (poly line) 24. Sidewall spacers, for example, multi-layer sidewall spacers, at sidewalls of the gate 24 of the transistor switches 21 and 22 and gate dielectrics between the gate 24 and the active semiconductor layers 22 and 35 may be provided (not shown for simplicity).

Moreover, the semiconductor device 100 comprises a first capacitor 25 and a second capacitor 26. The inner electrode 27 of the first capacitor 25 is electrically connected to the (raised) source or drain region 28 of the first switching transistor 21 and the outer electrode 29 of the second capacitor 26 is electrically connected to the wafer bulk 30. Similarly, the outer electrode 31 of the first capacitor 25 is electrically connected to the wafer bulk 30 and the inner electrode 32 of the second capacitor 26 is electrically connected to the (raised) source or drain region 33 of the second switching transistor 22. The entire structure is isolated from other devices by an isolation region 40, for example, including shallow trench isolations (STI) formed in the wafer. In particular, the semiconductor device 100 may be an FDSOI device with a fully depleted semiconductor layer 35 formed on a buried oxide layer 34. The buried oxide layer 34 may be made of the same material, for example, silicon dioxide, as the isolation region 40. The inner electrodes 27, 32 and outer electrodes 29, 31 of the first and second capacitors 25 and 26 are respectively isolated from each other by capacitor dielectric layers 36 and 37.

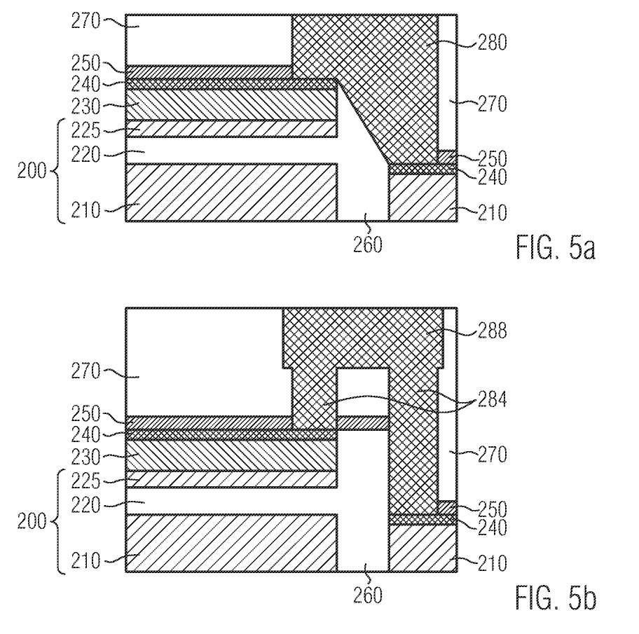

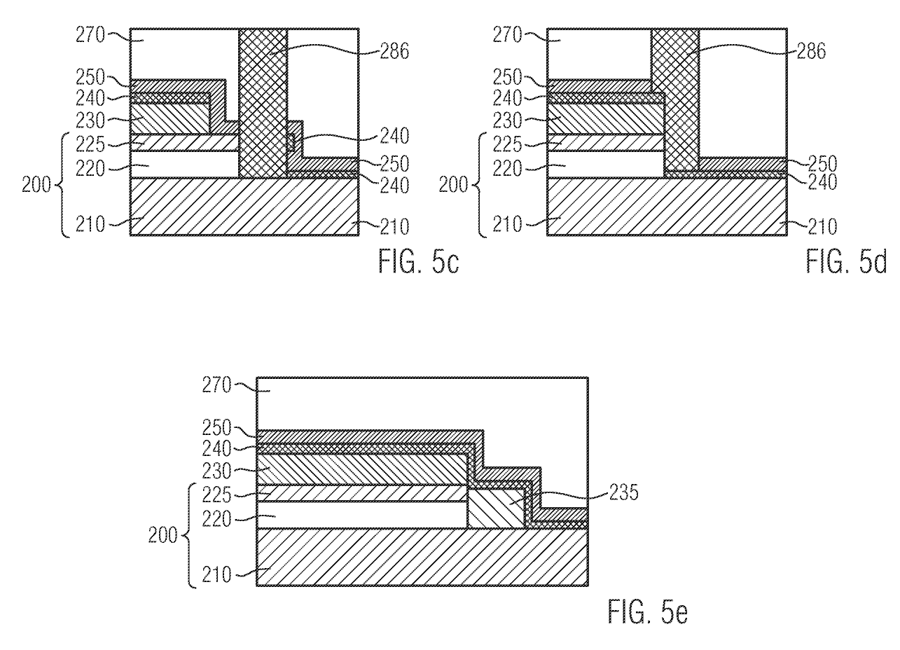

Furthermore, electrical contacts 50 are formed between the wafer bulk 30 and the source/drain regions 28, 33 of the first switching transistor 21 and the second switching transistor 22. Details of the contacts are described below with reference to FIGS. 5a-5c. Due to the contacts 50, the outer electrode 29 of the second capacitor 26 gets electrically connected to the source/drain region 33 of the first transistor switch 21 and the outer electrode 31 of the first capacitor 25 gets electrically connected to the source/drain region 28 of the second transistor switch 22. In conclusion, the capacitors 25 and 26 are cross-coupled via the first and second transistor switches 21 and 22 (confer also FIG. 2).

According to the example shown in FIGS. 2 and 3a-3d, a charge pump device can be provided that comprises trench capacitors cross-coupled via transistor switches sharing a common control gate. By the provided configuration, the spatial area in an SOI wafer occupied by a charge pump device may be significantly reduced as compared to the art.

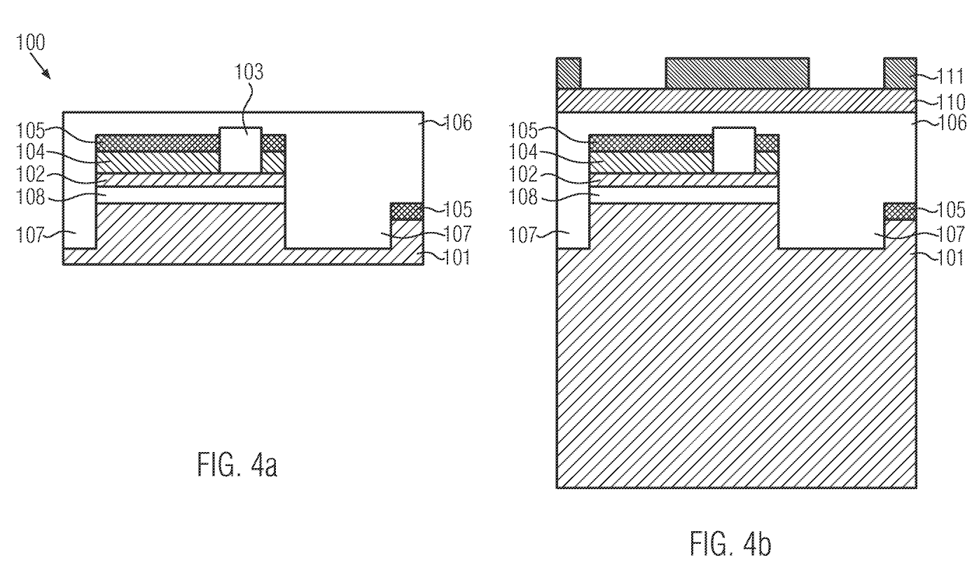

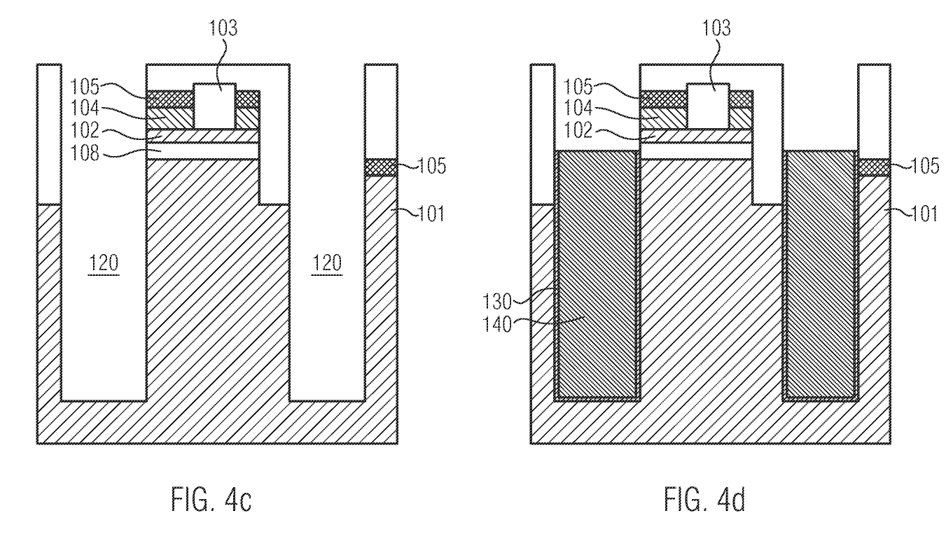

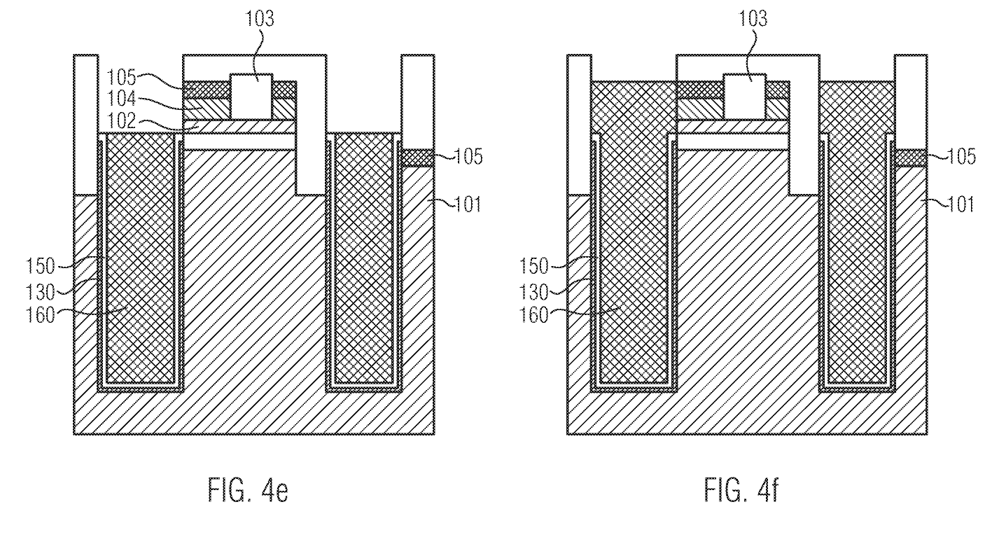

A process flow for manufacturing a semiconductor device comprising a charge pump in accordance with the present disclosure is illustrated in FIGS. 4a-4f. For example, a semiconductor device similar to the semiconductor device 100 illustrated in FIGS. 3a-3c may be formed by this process flow. FIG. 4a shows a semiconductor device 100 in a manufacturing stage wherein it comprises a semiconductor bulk substrate 101 and a semiconductor layer 102 formed over the semiconductor bulk substrate 101. The bulk semiconductor substrate 101 may be a silicon substrate, in particular, a single crystal silicon substrate. N-well and/or P-well regions may be implanted in the semiconductor bulk substrate 101. Other materials may be used to form the semiconductor substrate such as, for example, germanium, silicon germanium, gallium phosphate, gallium arsenide, etc. The semiconductor layer 102 may be comprised of any appropriate semiconductor material, such as silicon, silicon/germanium, silicon/carbon, other II-VI or III-V semiconductor compounds and the like. The semiconductor layer 102 may have a thickness suitable for forming a fully depleted field effect transistor, for example, a thickness in a range from about 5-8 nm. In particular, the semiconductor layer 102 may include an embedded strain-inducing or strained material, for example, an SiGe material, to induce strain in the channel region of a FET.

A gate electrode 103 of a FET is formed over the semiconductor layer 102. A gate dielectric (not shown) may be formed between the gate electrode 103 and the semiconductor layer 102. The gate electrode layer 103 may comprise a metal gate. The material of the metal gate may depend on whether the transistor device to be formed is a P-channel transistor or an N-channel transistor. In embodiments wherein the transistor device is an N-channel transistor, the metal may include La, LaN or TiN. In embodiments wherein the transistor device is a P-channel transistor, the metal may include Al, AlN or TiN. The metal gate may include a work function adjusting material, for example, TiN. In particular, the metal gate may comprise a work function adjusting material that comprises an appropriate transition metal nitride, for example, those from groups 4-6 in the periodic table, including, for example, titanium nitride (TiN), tantalum nitride (TaN), titanium aluminum nitride (TiAlN), tantalum aluminum nitride (TaAlN), niobium nitride (NbN), vanadium nitride (VN), tungsten nitride (WN) and the like, with a thickness of about 1-60 nm. Moreover, the effective work function of the metal gate may be adjusted by added impurities, for example, Al, C or F. Moreover, the gate electrode layer 103 may comprise a polysilicon gate at the top of the metal gate. Sidewall spacers (not shown), for example, comprising silicon dioxide and/or silicon nitride, may be formed at sidewalls of the gate electrode 103.

Raised source/drain regions 104 are formed on the semiconductor layer 102. Formation of the raised source/drain regions 104 may include epitaxially growing a semiconductor material on the semiconductor layer 102 and appropriate doping of the same after or during the epitaxial growth. It should be noted that the epitaxial growth of the material of the raised source/drain regions 104 on the surface of the semiconductor bulk substrate 101 in the area where the semiconductor layer 102 is removed (see right-hand side of FIG. 4a) may be blocked in order to reliably avoid shortening of a capacitor to be built (see also description below).

A silicide layer 105, for example, comprised of NiSi, may be formed on the raised source/drain regions 104. For this purpose, a metal layer may be deposited on the raised source/drain regions 104 and an anneal process may be performed for initiating a chemical reaction between the metal of the metal layer and the semiconductor material of the raised source/drain regions 104. The silicidation process is known to improve electrical contacts of the raised source/drain regions 104. In the shown example, the silicide layer 105 is also formed on a part of the semiconductor bulk substrate 101. In principle, it could also be formed on top of the gate electrode 103.

Furthermore, the semiconductor device 100 comprises an isolation structure 106 comprising shallow trench isolations (STI) 107. A buried oxide layer 108 also contributes to the isolation structure 106 that may be formed of the same material, for example, silicon dioxide, in all shown regions. The buried oxide layer 108 may include a dielectric material, such as silicon dioxide, and may be an ultra-thin buried oxide (UT-BOX) having a thickness in a range from about 10-20 nm. The semiconductor bulk substrate 101, the buried oxide layer 108 and the semiconductor layer 102 may constitute an FDSOI substrate.

For example, an (FD)SOI wafer comprising the semiconductor bulk substrate 101, the buried oxide layer 108 and the semiconductor layer 102 may be provided, the gate electrode 103 may be formed over the (FD)SOI wafer, the raised source/drain regions 104 and the silicide layer 105 and the STIs 107 are formed by etching trenches into the semiconductor layer 102, the BOX layer 108 and the semiconductor bulk substrate 101 and filling the same with a dielectric material and, subsequently, an isolation layer is deposited over the entire configuration and polished such that the isolation structure 106 results.

As shown in FIG. 4b, a hard mask 110, for example, a nitride mask, is formed over the configuration shown in FIG. 4a, for example, on the isolation structure 106. A photoresist layer 111 is formed on the hard mask 110 in order to pattern the hard mask by photolithography, i.e., the material of the hard mask 110 that is exposed by the openings of the photoresist layer 111 is removed, for example, by etching, and trenches 120 are etched in the structure, as shown in FIG. 4c, using the patterned hard mask 110 as an etching mask.

FIG. 4c shows the semiconductor device 100 after removal of the patterned hard mask 110 and photoresist layer 111. The hard mask 110 is patterned such that the right one of the trenches 120 is formed through the isolation structure 106 without contacting the raised source/drain region 104 and such that the left one of the trenches 120 is partly formed through the raised source/drain region 104. The right one of the trenches 120 is formed such that the right sidewall of the same is in contact with the silicide layer 105 formed on the semiconductor bulk substrate 101.

FIG. 4d shows the semiconductor device 100 in a further developed manufacturing stage. An outer capacitor electrode layer 130, for example, a layer comprising or consisting of a metal material, is formed within the trenches 120 shown in FIG. 4c. For example, a TiN material is deposited to form the outer capacitor electrode layer 130. After formation of the outer capacitor electrode layer 130, a dummy material 140 is filled in and the filled trenches are recessed to about the height of the buried oxide layer 108 and excessive material of the outer capacitor electrode layer 130 is removed to obtain the semiconductor device 100 as shown in FIG. 4d.

After removal of the excessive material of the outer capacitor electrode layer 130, the dummy material 140 is removed. After removal of the dummy material 140, a capacitor dielectric layer (node) 150 is formed on the outer capacitor electrode layer 130 and an inner capacitor electrode layer 160, for example, a metal layer, is formed on the capacitor dielectric layer 150 and, after recess to the upper surface of the buried oxide layer 108 and removal of excessive material of the capacitor dielectric layer 150, the semiconductor device 100 in the manufacturing stage shown in FIG. 4e results. The capacitor dielectric layer 150 may be formed of a high-k material with a dielectric constant higher than silicon dioxide, for example, with k>3 or 5. Both the outer capacitor electrode layer 130 and the inner capacitor electrode layer 160 are isolated from the semiconductor layer 102. The outer capacitor electrode layer 130 of the right capacitor structure is in contact with the silicide layer 105 formed on the semiconductor bulk substrate 101 that may represent a well tap contact of a tap cell provided for back-biasing of a transistor device.

After removal of the excessive material of the capacitor dielectric layer 150, additional material of the inner capacitor electrode 160 (or a different metal comprising material) is deposited to extend the inner capacitor electrode 160 such that the same gets into contact with the raised source/drain region 104 and the silicide layer 105 formed on the source/drain region 104, as shown in FIG. 4f. Since direct (electrical) contact between the inner capacitor electrode 160 and the raised source/drain region 104 is formed, no additional metal bridge must be formed as it is necessary in charge pump devices of the art. The realization of the capacitors in the form of trench capacitors allows for space saving as compared to conventionally formed charge pump devices.

As described above with reference to FIG. 2, electrical contacts 50 are formed between the wafer bulk 30 and the source/drain regions 28, 33 of the first switching transistor 21 and the second switching transistor 22 of an exemplary charge pump configuration. Such a contact has, for example, to be formed between the silicide layer 105 formed on the surface of the semiconductor bulk substrate 101 and the raised source/drain region 104 illustrated in FIGS. 4a-4f.

FIGS. 5a-5e show examples of realizations of these electrical contacts, for example, the electrical contacts 50 shown in FIG. 2. FIG. 5a shows a configuration comprising an SOI substrate 200 comprising a semiconductor bulk substrate 210, a buried oxide layer 220 formed on the semiconductor bulk substrate 210 and a semiconductor layer 225 formed on the buried oxide layer 220. A raised source/drain region 230 is formed on the semiconductor layer 225. A silicide layer 240 and an optional nitride layer 250 formed by plasma enhanced atomic deposition are provided on the raised source/drain region 230 and on an exposed surface of the semiconductor bulk substrate 210. The SOI substrate 200 and the region of the semiconductor bulk substrate 210 where the buried oxide layer 220 and semiconductor layer 230 are removed are separated from each other by an isolation layer 260. The isolation layer 260 may be part of an STI. Another isolation layer 270 is formed on the plasma enhanced nitride layer 250. Materials for the different layers may be chosen as described above with reference to FIG. 4a, for example (the same holds for the examples described with reference to FIGS. 5b-5e below). In particular, the semiconductor bulk substrate 210, the semiconductor layer 225 and the raised source/drain region 230 may comprise silicon and the isolation layers 220, 260, 270 may comprise silicon dioxide and the silicide layer 240 may comprise NiSi.

In the example shown in FIG. 5a, a contact between the silicide layer 240 formed on the exposed surface of the semiconductor bulk substrate 210 and the silicide layer 240 formed on the raised source/drain region 230 is formed by means of a rectangular contact (Carec) 280. The Carec 280 may be formed by depositing a metal-containing material, for example, after opening the isolation layer 270 and partial removal of the plasma enhanced nitride layer 250 to expose portions of the silicide layer 240 formed on the raised source/drain region 230 and the semiconductor bulk substrate 210, respectively. FIG. 5b shows an alternative version wherein the electrical contact between the semiconductor bulk substrate 210 and the raised source/drain region 230 is provided by two regular contacts 284 that are electrically connected with each other by a conductive structure 288 formed in an overlying metallization layer, for example, the first metallization (interconnection) layer.

FIGS. 5c and 5d show alternative examples wherein the electrical contact between the semiconductor bulk substrate 210 and the raised source/drain region 230 is provided by a single regular contact 286. FIGS. 5c and 5d, respectively, show configurations comprising an SOI substrate 200 comprising a semiconductor bulk substrate 210, a buried oxide layer 220 formed on the semiconductor bulk substrate 210 and a semiconductor layer 225 formed on the buried oxide layer 220. A raised source/drain region 230 is formed on the semiconductor layer 225. A silicide layer 240 and a nitride layer 250 are provided on the raised source/drain region 230 and on an exposed surface of the semiconductor bulk substrate 210. For example, the nitride layer 250 may be a TiN layer formed by atomic layer deposition or an Si₃N₄ layer formed by plasma enhanced chemical vapor deposition. An isolation layer 270 is formed over the nitride layer 250. In the example shown in Figure Sc, the regular contact 286 is formed through the isolation layer 270, the plasma enhanced nitride layer 250, the semiconductor layer 225 and the buried oxide layer 220.

Moreover, a regular contact 286 is formed in contact with the silicide layer 240, a part of which was formed on a side surface of the buried oxide layer 220 and the semiconductor layer 225. Electrical contact between the silicided raised source/drain region 230 and the silicided surface of the semiconductor bulk substrate 210 is achieved by the contact 286 via the silicide layer 240 and the plasma enhanced nitride layer 250. The same holds for the example shown in FIG. 5d where the contact 286 is partly formed on a sidewall of the SOI substrate 200, the surface of the silicide layer 240 formed on the raised source/drain region 230 and partly on the surface of the silicide layer 240 formed on the surface of the semiconductor bulk substrate 210.

FIG. 5e shows an alternative example wherein the electrical contact between the semiconductor bulk substrate 210 and the raised source/drain region 230 is provided without an additional contact element. This example basically differs from the previous ones in that an additional partial source/drain region 235 representing a contact element is formed on the surface of the semiconductor bulk substrate 210 and that a silicide layer 240 and an optional nitride layer 250 formed by plasma enhanced atomic deposition, for example, are provided on the additional partial source/drain region 235. In other words, electrical contacting in this case is provided by a silicide layer 240 and an optional nitride layer 250 continuously formed over the raised source/drain region 230, the additional partial source/drain region 235 and the semiconductor bulk substrate 210.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A semiconductor device comprising a fully depleted silicon-on-insulator (FDSOI) substrate and a charge pump device, wherein:
said FDSOI substrate comprises a semiconductor bulk substrate; and
said charge pump device comprises:
a transistor device formed in and on said FDSOI substrate; and
a trench capacitor formed in said semiconductor bulk substrate and electrically connected to said transistor device.

2. A semiconductor device, comprising:
a semiconductor bulk substrate;
a first transistor device comprising a first source/drain region;
a second transistor device comprising a second source/drain region;
a first trench capacitor comprising a first inner capacitor electrode and a first outer capacitor electrode; and
a second trench capacitor comprising a second inner capacitor electrode and a second outer capacitor electrode;
wherein said first inner capacitor electrode is connected to said first source/drain region and said second inner capacitor electrode is connected to said second source/drain region.

3. The semiconductor device of claim 2, wherein said first outer capacitor electrode and said second outer capacitor electrode are connected to said semiconductor bulk substrate.

4. The semiconductor device of claim 2, wherein said first and second transistor devices share a common gate electrode.

5. The semiconductor device of claim 2, wherein said first and second transistor devices comprise channel regions and said channel regions are formed in a semiconductor layer formed on a buried oxide layer that is formed on said semiconductor bulk substrate.

6. The semiconductor device of claim 2, wherein at least one of said first and second source/drain regions is a raised source/drain region.

7. The semiconductor device of claim 2, wherein said first and second transistor devices are formed in and over said semiconductor bulk substrate and said first and second trench capacitors are at least partially formed in said semiconductor bulk substrate.

8. The semiconductor device of claim 2, wherein said first outer capacitor electrode is connected to a first silicide layer formed on a first portion of said semiconductor bulk substrate and said second outer capacitor electrode is connected to a second silicide layer formed on a second portion of said semiconductor bulk substrate.

9. The semiconductor device of claim 2, wherein said first inner capacitor electrode is connected to a first silicide layer formed on said first source/drain region and said second inner capacitor electrode is connected to a second silicide layer formed on said second source/drain region.

10. The semiconductor device of claim 2, wherein a silicide layer is formed on a portion of said semiconductor bulk substrate and said silicide layer is connected to said first source/drain region by a first electrical contact and to said second source/drain region by a second electrical contact.

11. An integrated circuit with a semiconductor device according to claim 2, further comprising a third transistor device formed in and over said semiconductor bulk substrate and wherein said semiconductor device is operable to back-bias said third transistor device.

12. A semiconductor device, comprising:
a first trench capacitor comprising a first inner capacitor electrode and a first outer capacitor electrode;
a second trench capacitor comprising a second inner capacitor electrode and a second outer capacitor electrode;
a first switching device; and
a second switching device;
wherein said first inner capacitor electrode and said second outer capacitor electrode are connectable to each other by said first switching device; and
wherein said first outer capacitor electrode and said second inner capacitor electrode are connectable to each other by said second switching device.

13. The semiconductor device of claim 12, wherein said first switching device is a first transistor device and said second switching device is a second transistor device and wherein said first and said second switching device share a common gate electrode.

14. The semiconductor device of claim 12, further comprising an input voltage source, a third switching device and a fourth switching device and wherein said first inner capacitor electrode and said first switching device are connectable to said input voltage source by said third switching device and said first outer capacitor electrode is connectable to ground by said fourth switching device.

15. A method of manufacturing a semiconductor device, comprising:
providing a semiconductor substrate comprising a semiconductor bulk substrate, a buried oxide layer formed on said semiconductor bulk substrate and a semiconductor layer formed on said buried oxide layer;
forming a first transistor device and a second transistor device in and over said semiconductor substrate; and
forming a first and a second trench capacitor at least partially in said semiconductor substrate;
wherein forming said first transistor device comprises forming a first source/drain region on said semiconductor layer and forming said second transistor device comprises forming a second source/drain region on said semiconductor layer, and
wherein forming said first trench capacitor comprises forming a first inner capacitor electrode in contact with said first source/drain region and a first outer capacitor electrode at least partially in said semiconductor substrate and forming said second trench capacitor comprises forming a second inner capacitor electrode in contact with said second source/drain region and a second outer capacitor electrode at least partially in said semiconductor substrate.

16. The method of claim 15, wherein forming said first transistor device comprises forming a first gate dielectric over said semiconductor substrate and forming said second transistor device comprises forming a second gate dielectric over said semiconductor substrate and wherein forming said first and second transistor devices comprises forming a continuous electrode layer over said first and second gate dielectrics.

17. The method of claim 15, wherein said first and second trench capacitors are formed after formation of said first and second transistor devices and wherein the formation of said first and second trench capacitors comprises forming a first and a second trench in said semiconductor substrate and forming said first inner and outer capacitor electrodes in said first trench and forming said second inner and outer capacitor electrodes in said second trench such that said first inner capacitor electrode is in contact with said first source/drain region and said second inner capacitor electrode is in contact with said second source/drain region.

18. The method of claim 15, further comprising a first silicide layer on said first source/drain region in contact with said first inner capacitor electrode and a second silicide layer on said second source/drain region in contact with said second inner capacitor electrode.

19. The method of claim 15, further comprising forming a first silicide layer on a first portion of said semiconductor bulk substrate, forming a second silicide layer on a second portion of said semiconductor bulk substrate, forming a first electrical contact between said first source/drain region and said first silicide layer and forming a second electrical contact between said second source/drain region and said second silicide layer.

20. The method of claim 15, further comprising forming a third transistor device in and over said semiconductor substrate and forming a tap contact of a tap cell provided for back-biasing of said third transistor device to a region of said third transistor device formed in said semiconductor substrate and contacting said first outer capacitor electrode of said first trench capacitor or said second outer capacitor electrode of said second trench capacitor to said tap contact.
